(19) United States
(12) Patent Application Publication
(10) Pub. No.: US 2024/0027493 A1
(43) Pub. Date: Jan. 25, 2024

(54) WIRING BOARD AND PROBE CARD

(71) Applicant: KYOCERA Corporation, Kyoto-shi, Kyoto (JP)

(72) Inventor: Yoshihiro TODA, Kyoto-shi (JP)

(73) Assignee: KYOCERA Corporation, Kyoto-shi, Kyoto (JP)

(21) Appl. No.: 18/038,639

(22) PCT Filed: Nov. 25, 2021
(86) PCT No.: PCT/JP2021/043263

§ 371 Date: May 24, 2023

(30) Foreign Application Priority Data
Nov. 27, 2020 (JP) 2020-196678

(51) Int. Cl. G01R 1/073; G01R 1/04; G01R 31/28

(52) U.S. Cl. CPC G01R 1/07342; G01R 1/0416; G01R 31/2889

(57) ABSTRACT

A wiring board includes an insulation substrate, a wiring conductor, a connection conductor, first and second wiring layers, and a groove. The insulation substrate includes a first face. The wiring conductor is located in or on and the connection conductor is located in the insulation substrate. A part of the wiring conductor is included at each of the first and second wiring layers. The groove includes an opening at the first face. The wiring conductor includes an electrode pad and a solid conductor. The solid conductor is included at the second wiring layer. The connection conductor includes first and second connection conductors, a second connection conductor, and an intersection part. The intersection part intersects the groove at the first wiring layer and is located between the first and second connection conductors. The first and second connection conductors are electrically continuous to the electrode pad and the solid conductor, respectively.

### TECHNICAL FIELD

The present disclosure relates to a wiring board and a probe card.

### BACKGROUND

Japanese Unexamined Patent Application Publication No. 2011-29424 describes a wiring board including an electrode pad. The wiring board includes a small strip part and a connection conductor. The small strip part can be readily removed by fracturing or the like. The connection conductor is located on the small strip part. The connection conductor is used to supply electric current to the electrode pad during electroplating applied to the electrode pad. After the electroplating, the small strip part of the wiring board is removed to cut off the connection conductor used for the electroplating from the wiring conductor. A desired wiring pattern can be thus obtained.

### SUMMARY

According to the present disclosure, a wiring board includes an insulation substrate, a wiring conductor, a connection conductor, a first wiring layer, a second wiring layer, and a groove. The insulation substrate includes a first face. The wiring conductor is located in or on the insulation substrate. The connection conductor is located in the insulation substrate. A part of the wiring conductor is included at the first wiring layer. A part of the wiring conductor is included at the second wiring layer. The groove includes an opening at the first face. The wiring conductor includes an electrode pad and a first solid conductor. The first solid conductor is included at the second wiring layer. The connection conductor includes a first connection conductor, a second connection conductor, and an intersection part. The intersection part intersects the groove at the first wiring layer. The intersection part is located between the first connection conductor and the second connection conductor. The first connection conductor is electrically continuous to the electrode pad. The second connection conductor is electrically continuous to the first solid conductor. The first wiring layer is located at the first face or under the first face. The second wiring layer is located under the first wiring layer.

According to the present disclosure, a probe card includes the wiring board mentioned above and a plurality of probe pins. The plurality of probe pins is connected to the wiring board.

### BRIEF DESCRIPTION OF THE DRAWINGS

FIG. 1 is a longitudinal sectional view of a part of a wiring board according to Embodiment 1 of the present disclosure.

FIG. 2A is a plan view of a first face of the wiring board illustrated in FIG. 1.

FIG. 2B is a sectional view, taken along a line B-B, of the wiring board illustrated in FIG. 1.

FIG. 2C is a sectional view, taken along a line C-C, of the wiring board illustrated in FIG. 1.

FIG. 3 is a longitudinal sectional view of a part of a wiring board according to Embodiment 2 of the present disclosure.

FIG. 4A is a plan view of a first face of the wiring board illustrated in FIG. 3.

FIG. 4B is a sectional view, taken along a line B-B, of the wiring board illustrated in FIG. 3.

FIG. 4C is a sectional view, taken along a line C-C, of the wiring board illustrated in FIG. 3.

FIG. 4D is a sectional view, taken along a line D-D, of the wiring board illustrated in FIG. 3.

FIG. 5 is a sectional view of a wiring board according to an alternative embodiment.

FIG. 6A is a plan view of a probe card according to an embodiment of the present disclosure.

FIG. 6B is a longitudinal sectional view of the probe card according to the embodiment of the present disclosure.

### DETAILED DESCRIPTION

Embodiments of the present disclosure are described in detail below with reference to the drawings.

### Embodiment 1

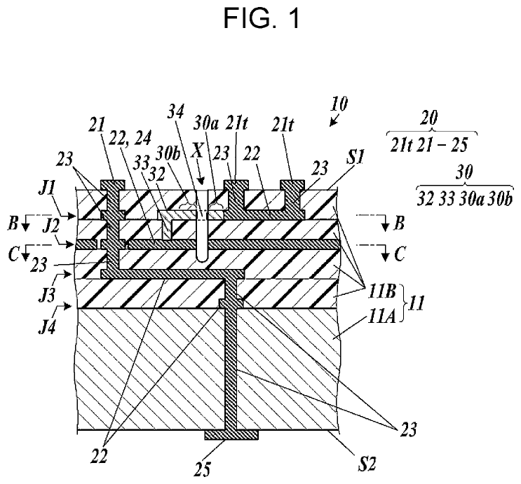

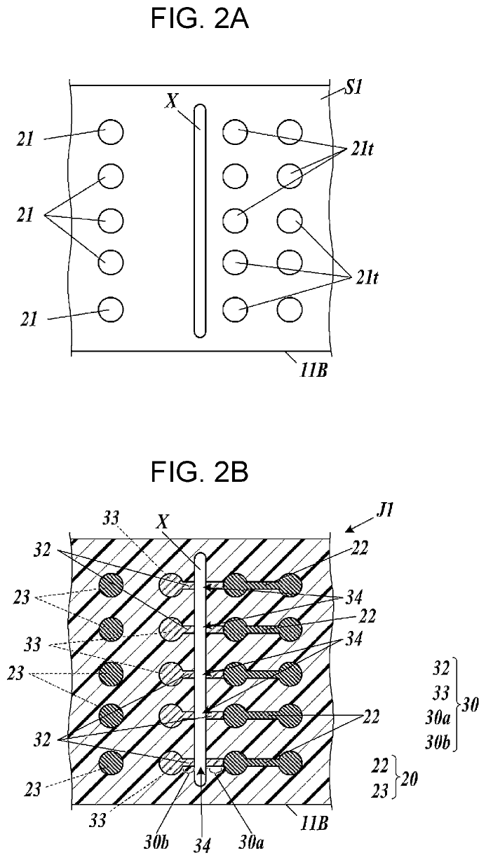

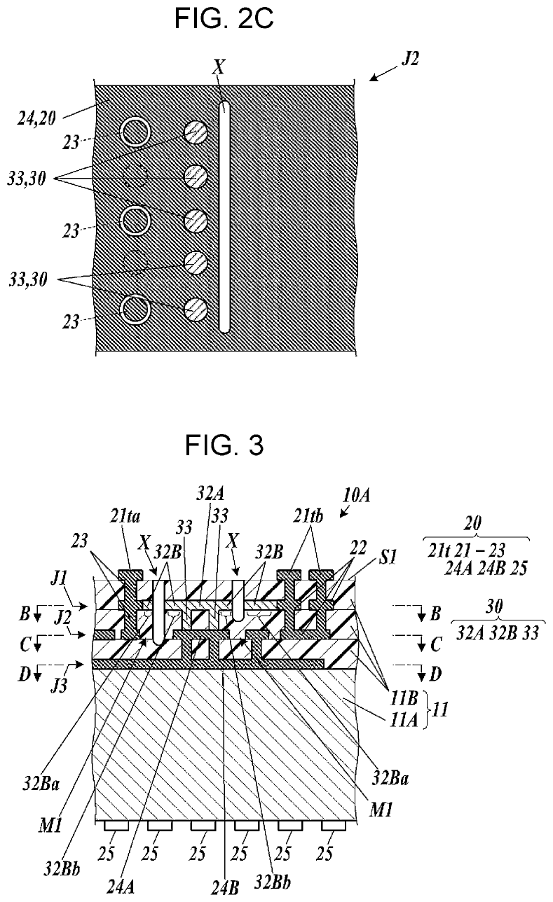

FIG. 1 is a longitudinal sectional view of a part of a wiring board 10 according to Embodiment 1 of the present disclosure. FIG. 2A is a plan view of a first face S1 of the wiring board 10. FIG. 2B is a sectional view of the wiring board 10 taken along a line B-B. FIG. 2C is a sectional view of the wiring board 10 taken along a line C-C.

According to Embodiment 1, the wiring board 10 includes an insulation substrate 11, a wiring conductor 20, and a connection conductor 30. The insulation substrate 11 includes the first face S1, and a second face S2 opposite from the first face S1. The wiring conductor 20 is located in or on the insulation substrate 11. The connection conductor 30 is located in the insulation substrate 11. Although the wiring conductor 20 and the connection conductor 30 are illustrated with different hatchings in the drawings, the wiring conductor 20 and the connection conductor 30 may include the same material and may be integral with each other. The wiring board 10 further includes multiple wiring layers (first to fourth wiring layers J1 to J4) therein. A layer of wiring conductor located at the first face S1 and the second face S2 may be also called wiring layer.

The insulation substrate 11 includes a first insulation substrate 11A made of a ceramic material, and a second insulation substrate 11B made of a resin material. The first insulation substrate 11A and the second insulation substrate 11B are stacked together. The insulation substrate 11 may be made of any material other than those exemplified above. The insulation substrate 11 is not necessarily a stack of two substrates each made of a different material. Alternatively, the insulation substrate 11 may be made of a single material.

The wiring conductor 20 is a conductor through which an electrical signal or voltage is to be transmitted. The wiring conductor 20 includes multiple electrode pads 21 and 21t, multiple electrodes 25, a film conductor 22, and a via-conductor 23. The electrode pads 21 and 21t are located on the first face S1. The electrodes 25 are located on the second face S2. The film conductor 22 is located in the first to fourth wiring layers J1 to J4. The via-conductor 23 is located between layers including the first face S1, the first to fourth wiring layers J1 to J4, and the second face S2. The first to third wiring layers J1 to J3 are located within the second insulation substrate 11B. The fourth wiring layer J4 is located between the first insulation substrate 11A and the second insulation substrate 11B. The first to fourth wiring layers J1 to J4 are arranged in this order as seen from the first face S1. The total number of wiring layers is not limited to the above-mentioned number. One or more wiring layers may be located within the first insulation substrate 11A.

The film conductor 22 of the wiring conductor 20 includes a solid conductor 24. A predetermined potential such as a ground potential or a power supply potential is supplied to the solid conductor 24. The solid conductor 24 refers to a conductor extending over an area greater than or equal to 30% of the area of a region of the wiring board 10 where the wiring conductor 20 is disposed (a region excluding a peripheral area where no wiring conductor 20 is disposed). The solid conductor 24 may include a through-hole through which the via conductor 23 passes, or a slit or notch that is provided to avoid interference with a given region. The solid conductor 24 corresponds to an example of a first solid conductor according to the present disclosure.

Electroplating is applied to the electrode pads 21 and 21t. The electroplating may include, for example, a nickel film and a gold film that are stacked sequentially. The nickel film has a thickness of about 1 μm to 10 μm. The gold film has a thickness of about 0.1 μm to 3 μm. The electroplating serves to protect the surfaces of the electrode pads 21 and 21t, and also improve bonding of a brazing filler metal, solder, or the like to the surfaces. The electrode pads 21 and 21t may include the following electrode pads: an electrode pad that is electrically continuous via the wiring conductor 20 to one of the electrodes 25 located on the opposite side from the electrode pads 21 and 21t; and an electrode pad that is electrically continuous to none of the electrodes 25 via the wiring conductor 20. As for the electrode pad 21t that is electrically continuous to none of the electrodes 25 located on the opposite side from the electrode pad 21t, or the electrode pad 21t for which a high resistance is present between the electrode pad 21t and the electrode 25, such an electrode pad 21t is unable to, during electroplating, receive sufficient current from the electrode 25 located on the opposite side from the electrode pad 21t.

The connection conductor 30 is a conductor that, during electroplating of the electrode pads 21 and 21t, has supplied current to the electrode pad 21t that is unable to receive current from the wiring conductor 20 alone or to the electrode pad 21t that is unable to receive sufficient current from the wiring conductor 20 alone. The connection conductor 30 includes a film conductor 32 and a via-conductor 33. The film conductor 32 is located at the first wiring layer J1. The via-conductor 33 is interposed between the first wiring layer J1 and the second wiring layer J2. The electrode pad 21t to which current has been supplied via the connection conductor 30 during electroplating will be hereinafter referred to also as “target electrode pad 21t”. The wiring conductor 20 may include multiple target electrode pads 21t.

The wiring board 10 further includes a groove X that is cut out of a part of the wiring board 10. Although the groove X is cut out of a part of the wiring board 10 with a laser beam, the groove X may be cut out of a part of the wiring board 10 with another beam such as an electron beam. The groove X may be filled with an insulative substance.

### <Relative Positioning of Target Electrode Pads, Connection Conductor, Solid Conductor, and Groove>

As illustrated in FIG. 2A, the target electrode pads 21t are located on the first face S1. In addition, the electrode pads 21 to which current is supplied without passing through the connection conductor 30 during electroplating are located on the first face S1. Although FIGS. 2A and 2B illustrate an example in which two mutually adjacent target electrode pads 21t are electrically continuous to each other via the wiring conductor 20 located at the first wiring layer J1, the target electrode pads 21t may be electrically non-continuous to each other, or the combination of target electrode pads 21t that are electrically continuous to each other may be different from the combination illustrated in FIGS. 2A and 2B.

As illustrated in FIG. 2B, the film conductor 32 of the connection conductor 30 includes a first connection conductor 30a, a second connection conductor 30b, and an intersection part 34 located between the first connection conductor 30a and the second connection conductor 30b. Although only one first connection conductor 30a and only one second connection conductor 30b are designated by the corresponding reference signs in FIG. 2B, one first connection conductor 30a and one second connection conductor 30b are likewise included in each of multiple connection conductors 30. Electrical continuity of the film conductor 32 to the target electrode pad 21t is established by connection of the film conductor 32 to the film conductor 22 of the wiring conductor 20. The respective film conductors 32 of the connection conductors 30 may have a linear shape. The intersection part 34 intersects the groove X. The first connection conductor 30a is electrically continuous to the target electrode pad 21t via the wiring conductor 20. The second connection conductor 30b is connected to the solid conductor 24 via the via-conductor 33. Each film conductor 32 having a linear shape is cut at the intersection part 34, and one portion and the other portion of each film conductor 32 that are located across the intersection part 34 from each other are not electrically continuous to each other.

As illustrated in FIG. 2C, the solid conductor 24 is located at the second wiring layer J2 and, in see-through plan view, overlaps the film conductor 32 of the connection conductor 30. The term “see-through plan” corresponds to a plane representing the interior as viewed in a see-through manner in a direction perpendicular to the first face S1. The same applies to the subsequent use of the term “see-through plan”. The solid conductor 24 may include a slit that intersects the groove X. Although not illustrated, the solid conductor 24 is electrically connected to the electrode 25 at a position different from the position of the section illustrated in FIG. 1.

The groove X includes an opening at the first face S1. According to Embodiment 1, the bottom of the groove X is located below the second wiring layer J2. In see-through plan view, a single groove X may extend so as to intersect multiple film conductors 32 of the connection conductors 30, or multiple grooves X may be located such that each single groove X intersects only one film conductor 32 of the connection conductor 30.

The position of the bottom of the groove X has a range of tolerance. The range of tolerance for the position of the bottom is from a depth between the first wiring layer J1 and the second wiring layer J2 to a depth between the second wiring layer J2 and the third wiring layer J3.

### <Manufacturing Method>

An exemplary method for manufacturing the wiring board 10 is described below. The first insulation substrate 11A, and the wiring conductor 20 located in or on the first insulation substrate 11A can be each formed by firing of a ceramic material and by a metallized conductor.

The second insulation substrate 11B is formed by, for example, multiple resin layers being stacked. The resin layers may be made of, for example, an insulative resin. Examples of the insulative resin include polyimide resin, polyamide-imide resin, siloxane-modified polyamide-imide resin, siloxane-modified polyimide resin, polyphenylene sulfide resin, wholly aromatic polyester resin, benzocyclobutene (BCB) resin, epoxy resin, bismaleimide triazine resin, polyphenylene ether resin, polyquinoline resin, and fluororesin. The resin layers may contain a filler for adjustment of formability and/or thermal expansion coefficient. Examples of the filler include inorganic fillers such as barium sulfate, barium titanate, amorphous silica, crystalline silica, fused silica, spherical silica, clay, magnesium carbonate, calcium carbonate, aluminum oxide, aluminum hydroxide, silicon nitride, aluminum nitride, boron nitride, alumina, magnesium oxide, magnesium hydroxide, titanium oxide, mica, talc, Neuburg silica, organic bentonite, and zirconium phosphate. The resin layers may contain one of the above-mentioned fillers alone, or any suitable combination of two or more of the above-mentioned fillers.

One resin layer of the second insulation substrate 11B may be formed by bonding a resin film to the layer under the resin layer, or may be formed by applying a liquid precursor resin onto the layer under the resin layer and then causing the applied resin to set. Once one resin layer is formed, a resist film with an opening corresponding to each of the via-conductor 23 and the film conductor 22 is formed on top of the resin layer. Then, a recess corresponding to the film conductor 22 and a through-hole corresponding to the via-conductor 23 are formed by etching or laser machining. Subsequently, an underlying conductor layer consisting of, for example, a chrome (Cr)-copper (Cu) alloy layer, or a titanium (Ti)-copper (Cu) alloy layer is formed within the recess and the through-hole in the resin layer by a thin-film forming method such as vapor deposition, sputtering, or ion plating. Subsequently, the recess and the through-hole are filled by plating or the like with a metal such as copper or gold. The resist is then removed. In this way, one resin layer, and the wiring conductor 20 or the connection conductor 30 that is located at the one resin layer can be formed. Such formation of a resin layer and the wiring conductor 20 or the connection conductor 30 is repeated to thereby form multiple resin layers, and the wiring conductor 20 or the connection conductor 30 that is located at each of the resin layers. On top of the last resin layer (the uppermost resin layer) of the resin layers that have been formed repeatedly, a resist film with an opening corresponding to the electrode pad 21 is formed. An underlying conductor layer is then formed at the opening by a thin-film forming method same as, and/or similar to, the above-mentioned thin-film forming method. A nickel film and a gold film are formed by electroplating on the underlying conductor layer for the electrode pad 21.

During electroplating, current is passed from the electrode 25 on the first insulation substrate 11A to the underlying conductor layer via the wiring conductor 20 and the connection conductor 30. Once the electroplating is completed, the resist is removed. A board including a stack of the first insulation substrate 11A and the second insulation substrate 11B is thus formed. The board at this point includes an unnecessary electrical continuity between the target electrode pad 21t and the wiring conductor 20 made via the connection conductor 30. The term “unnecessary” as used herein means unnecessary when the wiring board 10 is in use.

Accordingly, to remove the unnecessary electrical continuity mentioned above, laser trimming is performed by using a laser beam applied from a side of the insulation substrate 11 corresponding to the first face S1 to cut the connection conductor 30. Through the laser trimming, the groove X having an opening at the first face S1, and the intersection part 34 where the connection conductor 30 and the groove X intersect are formed, and the connection conductor 30 is cut at the intersection part 34. All unnecessary electrical continuities are then removed. The wiring board 10 is thus fabricated.

As described above, according to Embodiment 1, the wiring board 10 includes the target electrode pad 21t, the solid conductor 24, and the connection conductor 30. The solid conductor 24 is located at the second wiring layer J2. The connection conductor 30 includes the intersection part 34 that intersects the groove X at the first wiring layer J1. The connection conductor 30 further includes the first connection conductor 30a and the second connection conductor 30b. The intersection part 34 is located between the first connection conductor 30a and the second connection conductor 30b. The second connection conductor 30b is electrically continuous to the solid conductor 24. The first connection conductor 30a is electrically continuous to the target electrode pad 21t. Accordingly, before the groove X is formed, sufficient electroplating can be applied to the electrode pad 21 through supply of current to the electrode pad 21 via the connection conductor 30. The groove X is then formed in the insulation substrate 11 by use of a beam or the like to thereby cut the connection conductor 30. A desired wiring pattern of the wiring conductor 20 is thus obtained.

In the wiring board 10 according to Embodiment 1, the opening of the groove X is located at the first face S1, the intersection part 34 where the connection conductor 30 and the groove X intersect is located at the first wiring layer J1 under the first face S1, and the solid conductor 24 is located at the second wiring layer J2 under the first wiring layer J1. Accordingly, even if the groove X that cuts the connection conductor 30 extends to reach the second wiring layer J2, this only results in a slit being formed in the solid conductor 24, and thus does not significantly affect the electrical characteristics of the wiring conductor 20. This means that a greater tolerance is allowed for the depth of the groove X that cuts the connection conductor 30. Therefore, even if a process employed to cut the connection conductor 30 requires a relatively large tolerance for the depth of the groove X, the complexity of such a process can be reduced. Using such a process makes it possible to provide the wiring board 10 in which the connection conductor 30 is cut with reduced complexity and with improved reliability.

According to Embodiment 1, the wiring board 10 includes the groove X that is a cutout made by a beam such as a laser beam. A trimming process that cuts the connection conductor 30 by use of a beam enables high-speed processing with relatively little complexity. Accordingly, the wiring board 10 having the groove X mentioned above includes the wiring conductor 20 for which the connection conductor 30 has been cut with reduced complexity and with improved reliability.

### Embodiment 2

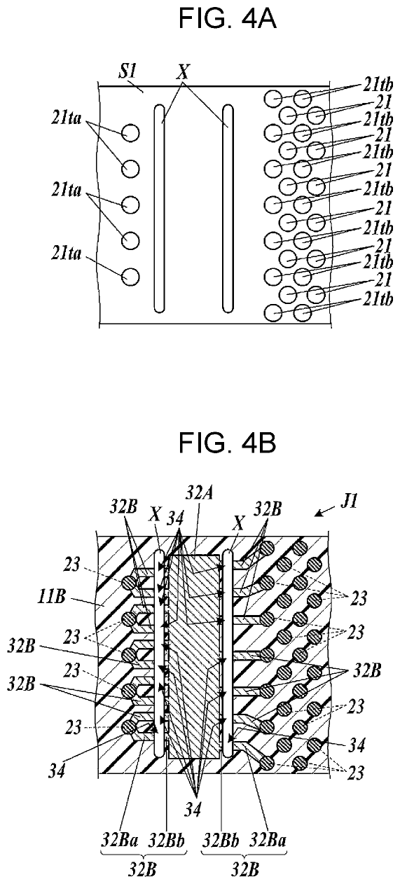

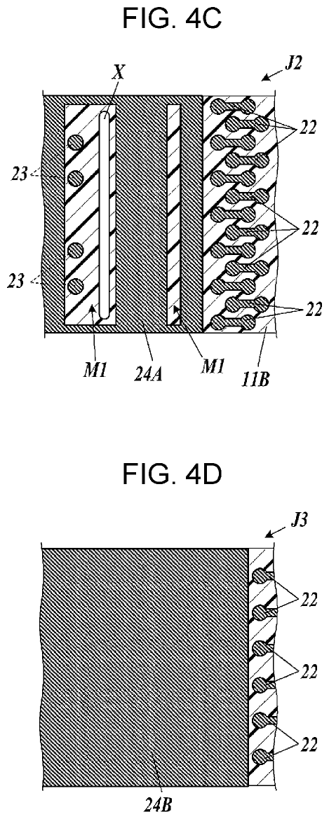

FIG. 3 is a longitudinal sectional view of a part of a wiring board according to Embodiment 2 of the present disclosure. FIG. 4A is a plan view of the first face S1 of the wiring board illustrated in FIG. 3. FIG. 4B is a sectional view, taken along a line B-B, of the wiring board illustrated in FIG. 3. FIG. 4C is a sectional view, taken along a line C-C, of the wiring board illustrated in FIG. 3. FIG. 4D is a sectional view, taken along a line D-D, of the wiring board illustrated in FIG. 3.

A wiring board 10A according to Embodiment 2 is substantially the same as, and/or similar to, the wiring board 10 according to Embodiment 1, except that the wiring conductor 20 and the connection conductor 30 differ in pattern from those of the wiring board 10. In the wiring board 10A according to Embodiment 2, multiple target electrode pads 21ta and 21tb are located on the first face S1 as illustrated in FIG. 4A. The target electrode pads 21ta and 21tb may be divided, for each individual region where these electrode pads are disposed, into a first group of target electrode pads 21ta located on the left-hand side of FIG. 4A, and a second group of target electrode pads 21tb located on the right-hand side of FIG. 4A.

As illustrated in FIG. 4B, the connection conductor 30 includes a common conductor 32A and multiple linear conductors 32B. The common conductor 32A is band-shaped and located at the first wiring layer J1. The linear conductors 32B are located at the first wiring layer J1. The term “band-shaped” as used herein means having a shape with a large lateral dimension in plan view relative to the linear conductors 32B. The common conductor 32A is connected to a first solid conductor 24A via multiple via-conductors 33 (see FIG. 3). In see-through plan view, the common conductor 32A is located between the first group of target electrode pads 21ta, and the second group of target electrode pads 21tb. The common conductor 32A may be disposed with its longitudinal direction aligned with the direction of arrangement of the first group of target electrode pads 21ta or the direction of arrangement of the second group of target electrode pads 21tb.

In see-through plan view, the groove X is located between the common conductor 32A and the first group of target electrode pads 21ta, and between the common conductor 32A and the second group of target electrode pads 21tb. The groove X may be disposed with its longitudinal direction aligned with the longitudinal direction of the common conductor 32A.

Each of the linear conductors 32B includes a first linear conductor 32Ba, a second linear conductor 32Bb, and the intersection part 34 that intersects the groove X. Although only two first linear conductors 32Ba and only two second linear conductors 32Bb are designated by the corresponding reference signs in FIG. 4B, one first linear conductor 32Ba and one second linear conductor 32Bb are likewise included in each of the linear conductors 32B. The intersection part 34 is located between the first linear conductor 32Ba and the second linear conductor 32Bb. The second linear conductor 32Bb is connected to the common conductor 32A, and the first linear conductor 32Ba is electrically continuous to the target electrode pad 21ta or 21tb via the wiring conductor 20 (the film conductor 22 and the via-conductor 23). One first linear conductor 32Ba may be electrically continuous to multiple target electrode pads 21tb, or multiple first linear conductors 32Ba may be electrically continuous to one target electrode pad 21ta.

As illustrated in FIG. 4C, the wiring conductor 20 includes the first solid conductor 24A located at the second wiring layer J2. The first solid conductor 24A includes an opening M1 that, in see-through plan view, overlaps the groove X (or the intersection part 34 of the linear conductor 32B). As illustrated in FIG. 4D, the wiring conductor 20 may further include a second solid conductor 24B at the third wiring layer J3. The second solid conductor 24B is positioned to overlap the groove X in see-through plan view.

According to Embodiment 2, the wiring board 10A may be manufactured by a method same as, and/or similar to, Embodiment 1 except that the wiring conductor 20 and the connection conductor 30 differ in pattern from those according to Embodiment 1.

According to Embodiment 2, the connection conductor 30 of the wiring board 10A includes the common conductor 32A as described above. This reduces the overall resistance of the connection conductor 30. As a result, in performing electroplating before the groove X is formed, current can be supplied to the target electrode pad 21ta or 21tb in a stable manner via the connection conductor 30. This makes it possible to easily form a coating of plating at a predetermined thickness on the target electrode pad 21ta or 21tb, and also to reduce thickness variations relative to other electrode pads 21.

With the wiring board 10A according to Embodiment 2, in response to the linear conductor 32B, which is connected to the target electrode pad 21ta, having an elongated length and the resistance of the connection conductor 30 thus increases, multiple linear conductors 32B (multiple first linear conductors 32Ba) are connected to one target electrode pad 21ta. This connection makes it possible to: provide stable supply of current to the target electrode pad 21ta via the connection conductor 30; easily form a coating of plating at a predetermined thickness on the target electrode pad 21ta; and reduce thickness variations relative to other electrode pads 21 and other electrode pads 21tb.

With the wiring board 10A according to Embodiment 2, the first solid conductor 24A includes the opening M1 that overlaps the intersection part 34 of the connection conductor 30 in see-through plan view. Accordingly, during the trimming process that cuts the connection conductor 30, the risk of the cutting energy (the laser energy in the case of laser trimming) being absorbed by the first solid conductor 24A can be reduced. Therefore, the risk of faulty or poor cutting of the connection conductor 30 due to insufficient energy can be reduced.

With the wiring board 10A according to Embodiment 2, the second solid conductor 24B, which overlaps the opening M1 in the first solid conductor 24A in see-through plan view, is located at the third wiring layer J3. Accordingly, even if the depth of the groove X reaches the third wiring layer J3 during the trimming process that cuts the connection conductor 30, this does not significantly affect the electrical characteristics of the wiring conductor 20. Therefore, a greater tolerance is allowed for the depth of the groove X that cuts the connection conductor 30. Even if the presence of the opening M1 in the first solid conductor 24A at the second wiring layer J2 makes it difficult to control the depth of the groove X, the greater tolerance allowed for the depth of the groove X helps to ensure that the depth of the groove X can be kept within the range of tolerance, and the connection conductor 30 can be thus cut with improved reliability.

### Alternative Embodiment

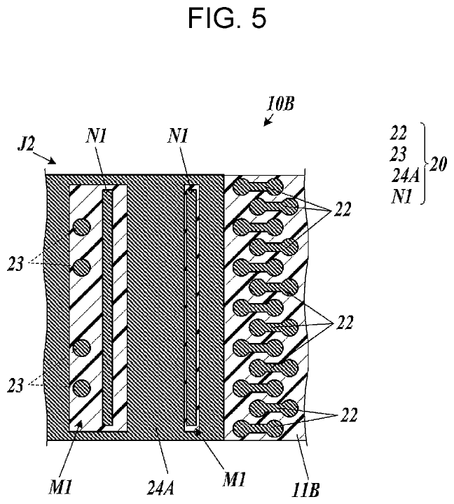

FIG. 5 is a sectional view of a wiring board according to an alternative embodiment. FIG. 5 is a sectional view taken along a line C-C in FIG. 3. A wiring board 10B according to the alternative embodiment is the same as, and/or similar to, Embodiment 2, except for the wiring conductor 20 located at the second wiring layer J2.

With the wiring board 10B according to the alternative embodiment, the first solid conductor 24A at the second wiring layer J2 includes the opening M1 that, in see-through plan view, overlaps the groove X (or the intersection part 34 of the linear conductor 32B). The wiring conductor 20 at the second wiring layer J2 includes a conductor strip N1. The conductor strip N1 is located within the opening M1 and overlaps the groove X (or the intersection part 34 of the linear conductor 32B). The conductor strip N1 may be a floating conductor that is not electrically continuous to the first solid conductor 24A, or may be a conductor that is partially connected to the first solid conductor 24A.

With the wiring board 10B according to the alternative embodiment, the first solid conductor 24A includes the opening M1 as described above. Accordingly, during the trimming process that cuts the connection conductor 30, the risk of the cutting energy (the laser energy in laser trimming) being absorbed by the first solid conductor 24A can be reduced. Therefore, the risk of faulty or poor cutting of the connection conductor 30 due to insufficient energy can be reduced. According to the alternative embodiment, the wiring board 10B includes the conductor strip N1 that is located within the opening M1 and that overlaps the groove X as described above. The conductor strip N1 is either unconnected to the first solid conductor 24A or only partially connected to the first solid conductor 24A. This helps to reduce, during the trimming process that cuts the connection conductor 30, the risk that the cutting energy (the laser energy in laser trimming) may, due to thermal conduction or the like, escape to the first solid conductor 24A and be absorbed by the first solid conductor 24A. Even if the cutting energy reaches the second wiring layer J2 during the trimming process, the cutting energy is used for cutting the conductor strip N1. This helps to reduce the risk of the cutting energy further reaching the third wiring layer J3 located under the second wiring layer J2. The above-mentioned configuration therefore makes it possible to provide the wiring board 10B whose connection conductor 30 has been cut with improved reliability, while reducing the risk of the electrical characteristics of the wiring conductor 20 being affected by the trimming process. The alternative embodiment helps to ensure that even if the film conductor 22 having a linear shape that overlaps the opening M1 of the first solid conductor 24A in see-through plan view is disposed at the wiring layer (third wiring layer J3) located under the first solid conductor 24A, the risk of the film conductor 22 being cut by the groove X is reduced.

### (Probe Card)

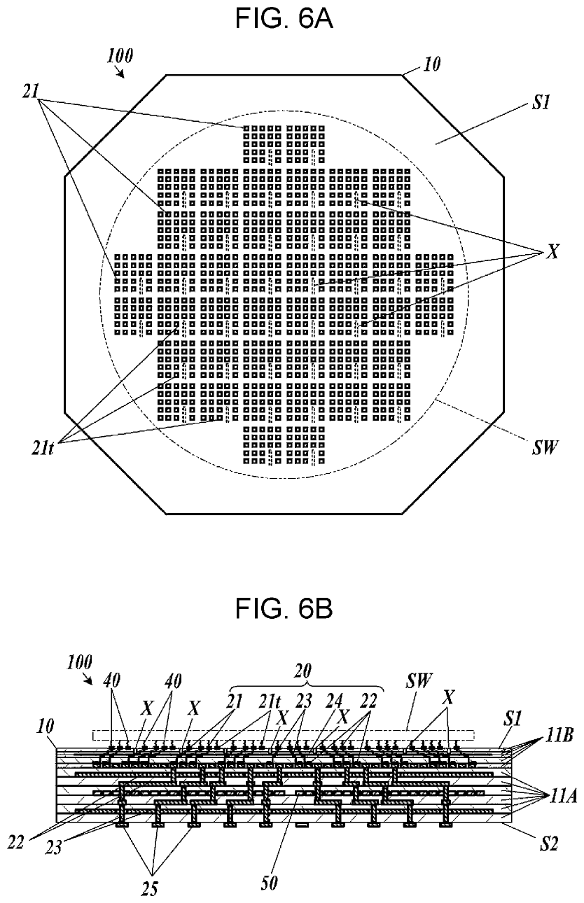

FIG. 6A is a plan view of a probe card according to an embodiment of the present disclosure. FIG. 6B is a longitudinal sectional view of the probe card according to the embodiment of the present disclosure. A probe card 100 according to the embodiment is a component to be incorporated into an apparatus for testing a semiconductor wafer SW provided with multiple semiconductor devices. The probe card 100 according to the embodiment includes the wiring board and multiple probe pins 40 each connected to a respective one of multiple electrode pads 21 and 21t disposed on the wiring board 10.

The probe pin 40 is made of a metal such as nickel or tungsten and joined to the electrode pad 21 or 21t via a conductive jointing material such as solder. The probe card 100 is interposed between a signal processing circuit and the semiconductor wafer SW to be tested. The signal processing circuit receives and/or outputs a signal or voltage used for testing. Each of the probe pins 40 contacts an electrode of a respective one of the semiconductor devices.

The wiring board 10 of the probe card 100 may be the wiring board according to Embodiment 1. Alternatively, the wiring board 10 of the probe card 100 may be the wiring board according to Embodiment 2, or the wiring board 10B according to the alternative embodiment. As illustrated in FIG. 6B, the first insulation substrate 11A of the wiring board 10 is a stack of multiple insulation layers and may contain the film conductor 22 in addition to the via-conductor 23. The first insulation substrate 11A may further include a heater line 50.

With the probe card according to the embodiment, the electrode pads 21 and 21t of the wiring board 10 each have a coating with stable thickness. This allows for stable joining of the probe pin 40 and improved reliability with respect to the joint where the probe pin 40 is to be joined.

Embodiments of the present disclosure have been described above. The wiring board and the probe card according to the present disclosure, however, are not limited to the above embodiments. Although the above embodiments contemplate use of the wiring board as a wiring board for a probe card, the wiring board according to the present disclosure may be used as, for example, a wiring board that incorporates an electronic device, an electrical device, or various electrical circuits. Although the above embodiments are directed to an example in which the opening of the groove is located at a face on which electrode pads are located, it may be located on a face different from the above-mentioned face. Although the above embodiments are directed to an example in which the first wiring layer at which the intersection part between the connection conductor and the groove exists is located under the first face at which the opening of the groove exists, the first wiring layer at which the intersection part exists may be located at the first face at which the opening of the groove exists. These and other details set forth in the embodiments may be changed as appropriate without departing from the scope of the present invention.

### INDUSTRIAL APPLICABILITY

The present disclosure is applicable to a wiring board and a probe card.

### REFERENCE SIGNS

10, 10A, 10B wiring board
11 insulation substrate
S1 first face
S2 second face
wiring conductor
21, 21t, 21ta, 21tb electrode pad
22 film conductor
23 via-conductor
24 solid conductor
24A first solid conductor
M1 opening
N1 conductor strip
24B second solid conductor
25 electrode
30 connection conductor
30a first connection conductor
30b second connection conductor
32 film conductor
32A common conductor
32B linear conductor
32Ba first linear conductor
32Bb second linear conductor
33 via-conductor
34 intersection part
X groove
J1 first wiring layer
J2 second wiring layer
J3 third wiring layer
J4 fourth wiring layer
100 probe card

1. A wiring board comprising:
an insulation substrate comprising a first face;
a wiring conductor located in or on the insulation substrate;
a connection conductor located in the insulation substrate;
a first wiring layer at which a part of the wiring conductor is included;
a second wiring layer at which a part of the wiring conductor is included; and
a groove comprising an opening at the first face,
wherein the wiring conductor comprises
an electrode pad, and
a first solid conductor included at the second wiring layer,
wherein the connection conductor comprises
a first connection conductor,
a second connection conductor, and
an intersection part intersecting the groove at the first wiring layer,
wherein the intersection part is located between the first connection conductor and the second connection conductor,
wherein the first connection conductor is electrically continuous to the electrode pad,
wherein the second connection conductor is electrically continuous to the first solid conductor,
wherein the first wiring layer is located at the first face or under the first face, and
wherein the second wiring layer is located under the first wiring layer.

2. The wiring board according to claim 1,
wherein the groove is a cutout made by a beam.

3. The wiring board according to claim 1, the wiring board comprising:
a plurality of the electrode pads,
wherein the connection conductor comprises
a plurality of linear conductors located at the first wiring layer, and
a common conductor located at the first wiring layer, the common conductor being band-shaped,
wherein each of the plurality of linear conductors comprises
a first linear conductor,
a second linear conductor, and
the intersection part located between the first linear conductor and the second linear conductor,
wherein the first linear conductor of each of the plurality of linear conductors is electrically continuous to one of the plurality of electrode pads, and
wherein the second linear conductor of each of the plurality of linear conductors is connected to the common conductor.

4. The wiring board according to claim 1,
wherein the connection conductor comprises a plurality of linear conductors, the plurality of linear conductors being electrically continuous to the electrode pad.

5. The wiring board according to claim 1,
wherein the first solid conductor comprises an opening, the opening overlapping the intersection part in see-through plan view.

6. The wiring board according to claim 5, further comprising:
a third wiring layer located under the second wiring layer; and
a second solid conductor located at the third wiring layer, the second solid conductor overlapping the opening in see-through plan view.

7. The wiring board according to claim 5,
wherein the wiring conductor comprises a conductor strip located within the opening, the conductor strip overlapping the intersection part in see-through plan view.

8. A probe card comprising;
the wiring board according to claim 1; and
a plurality of probe pins connected to the wiring board.

9. The wiring board according to claim 2, the wiring board comprising:
a plurality of the electrode pads,
wherein the connection conductor comprises
a plurality of linear conductors located at the first wiring layer, and
a common conductor located at the first wiring layer, the common conductor being band-shaped,
wherein each of the plurality of linear conductors comprises
a first linear conductor,
a second linear conductor, and
the intersection part located between the first linear conductor and the second linear conductor,
wherein the first linear conductor of each of the plurality of linear conductors is electrically continuous to one of the plurality of electrode pads, and
wherein the second linear conductor of each of the plurality of linear conductors is connected to the common conductor.

10. The wiring board according to claim 2,
wherein the connection conductor comprises a plurality of linear conductors, the plurality of linear conductors being electrically continuous to the electrode pad.

11. The wiring board according to claim 3,
wherein the connection conductor comprises a plurality of linear conductors, the plurality of linear conductors being electrically continuous to the electrode pad.

12. The wiring board according to claim 9,
wherein the connection conductor comprises a plurality of linear conductors, the plurality of linear conductors being electrically continuous to the electrode pad.

13. The wiring board according to claim 2,
wherein the first solid conductor comprises an opening, the opening overlapping the intersection part in see-through plan view.

14. The wiring board according to claim 3,
wherein the first solid conductor comprises an opening, the opening overlapping the intersection part in see-through plan view.

15. The wiring board according to claim 9,
wherein the first solid conductor comprises an opening, the opening overlapping the intersection part in see-through plan view.

16. The wiring board according to claim 4,
wherein the first solid conductor comprises an opening, the opening overlapping the intersection part in see-through plan view.

17. The wiring board according to claim 10,
wherein the first solid conductor comprises an opening, the opening overlapping the intersection part in see-through plan view.

18. The wiring board according to claim 11,
wherein the first solid conductor comprises an opening, the opening overlapping the intersection part in see-through plan view.

19. The wiring board according to claim 12,
wherein the first solid conductor comprises an opening, the opening overlapping the intersection part in see-through plan view.
